(19) United States
(12) Patent Application Publication
(10) Pub. No.: US 2025/0253006 A1
(43) Pub. Date: Aug. 7, 2025

(54) MEMORY REPAIR FLAG TOKEN COUNTER

(71) Applicant: Micron Technology, Inc., Boise, ID (US)

(72) Inventors: William P. Yu, Boise, ID (US); Arnel S. Sim, Boise, ID (US); Azarias Dolores De La Cruz, Boise, ID (US); Junxian Ding, Boise, ID (US)

(21) Appl. No.: 19/046,319

(22) Filed: Feb. 5, 2025

Related U.S. Application Data
(60) Provisional application No. 63/550,333, filed on Feb. 6, 2024.

(51) Int. Cl. G11C 29/20; G11C 29/44

(52) U.S. Cl. CPC G11C 29/20; G11C 29/44

(57) ABSTRACT

Control circuitry (e.g., for a memory device in a system such as a CXL system) can receive counter values indicating a count of available repair resources for addressable portions of a memory device array. The control circuitry can store the counter values as repair flag tokens associated with respective corresponding portions of the addressable portions of the memory device array. Responsive to detecting an error in a first addressable portion of the addressable portions of the memory device array, the control circuitry can change the repair flag token associated with the first addressable portion where the error was detected.

### PRIORITY APPLICATION

This application claims the benefit of priority to U.S. Provisional Application Ser. No. 63/550,333, filed Feb. 6, 2024, which is incorporated herein by reference in its entirety.

### BACKGROUND

Memory devices for computers or other electronic devices may be categorized as volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), static RAM (SRAM), erasable programmable ROM (EPROM), resistance variable memory, phase-change memory, storage class memory, resistive random-access memory (RRAM), and magnetoresistive random-access memory (MRAM), among others. Persistent memory is an architectural property of the system where the data stored in the media is available after system reset or power-cycling. In some examples, non-volatile memory media may be used to build a system with a persistent memory model.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system.

Various protocols or standards can be applied to facilitate communication between a host and one or more other devices such as memory buffers, accelerators, or other input/output devices. In an example, an unordered protocol such as Compute Express Link (CXL) can be used to provide high-bandwidth and low-latency connectivity.

### BRIEF DESCRIPTION OF THE SEVERAL VIEWS OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally a block diagram of an example computing system including a host and a memory device.

FIG. 2 illustrates generally an example of a compute express link (CXL) system.

FIG. 3 illustrates generally an example of a CXL system implementing a virtual hierarchy for managing transactions.

FIG. 4 illustrates generally an example of a CXL memory device.

FIG. 5 illustrates an example repair token counter data structure.

FIG. 6 illustrates an example of a method for tracking availability of memory repair resources.

FIG. 7 illustrates a block diagram of an example machine with which, in which, or by which any one or more of the techniques discussed herein can be implemented.

### DETAILED DESCRIPTION

Compute Express Link (CXL) is an open standard interconnect configured for high-bandwidth, low-latency connectivity between host devices and other devices such as accelerators, memory devices, memory buffers, and other I/O devices. CXL was designed to facilitate high-performance computational workloads by supporting heterogeneous processing and memory systems. CXL enables coherency and memory semantics on top of Peripheral Component Interconnect Express (PCIe)-based I/O semantics for optimized performance.

In some examples, CXL is used in applications such as artificial intelligence, machine learning, analytics, cloud infrastructure, edge computing devices, communication systems, and elsewhere. Data processing in such applications can use various scalar, vector, matrix, and spatial architectures that can be deployed in central processing unit (CPU), graphics processing unit (GPU), field programmable gate array (FPGA), smart network interface cards (NICs), or other accelerators that can be coupled using a CXL link.

CXL supports dynamic multiplexing using a set of protocols that includes input/output (CXL.io, based on PCIe), caching (CXL.cache), and memory (CXL.memory or CXL.mem) semantics. In an example, CXL can be used to maintain a unified, coherent memory space between the CPU (e.g., a host device or host processor) and any memory on the attached CXL device. This configuration allows the CPU and the CXL device to share resources and operate on the same memory region for higher performance, reduced data movement, and reduced software stack complexity. In an example, the CPU is primarily responsible for maintaining or managing coherency in a CXL environment. Accordingly, CXL can be leveraged to help reduce device cost and complexity, as well as overhead traditionally associated with coherency across an I/O link.

CXL runs on PCIe PHY and provides full interoperability with PCIe. In an example, a CXL device starts link training in a PCIe Gen 1 Data Rate and negotiates CXL as its operating protocol (e.g., using the alternate protocol negotiation mechanism defined in the PCIe 5.0 specification) if its link partner supports CXL. Devices and platforms can thus more readily adopt CXL by leveraging the PCIe infrastructure and without having to design and validate the PHY, channel, channel extension devices, or other upper layers of PCIe.

In an example, CXL supports single level switching to enable fan-out to multiple devices. This enables multiple devices in a platform to migrate to CXL, while maintaining backward compatibility and the low-latency characteristics of CXL. In an example, CXL can provide a standardized compute fabric that supports pooling of multiple logical devices (MLD) and single logical devices such as using a CXL switch connected to several host devices or nodes (e.g., Root Ports). This feature enables servers to pool resources such as accelerators and/or memory that can be assigned according to workload. For example, CXL can help facilitate resource allocation or dedication and release. In an example, CXL can help allocate and deallocate memory to various host devices according to need. This flexibility helps designers avoid over-provisioning while ensuring best performance.

Data center operators, cloud service providers, and other users aim to avoid memory downtime so that they can provide expected levels of service to their end users. Therefore, manufacturers of memory devices are always looking for ways to improve the Reliability, Availability, and Serviceability (RAS) of memory devices. Repair time should be minimized and done with the goal of improving RAS. The inventors have provided a system and method for minimizing downtime needed for servicing and repair of memory devices.

Post Package Repair (PPR) allows systems to repair failed portions of memory. One type of PPR, referred to as hard PPR (hPPR), is persistent such that a repair is permanent after a repair row is assigned. DDR4 devices provide one repair row address per memory bank. However, DDR4 devices do not provide a way to query whether an hPPR resource is available. DDR5 devices also provide at least one repair per row address per bank. Both LPDDR5 and DDR5 devices provide a Mode Register to query hPPR resource availability. A read of this Mode Register returns a flag status indicating availability of a resource. However, it can be inefficient to perform repairs with this Mode Register, especially for CXL memory modules (CMMs) requiring multiple repairs, and sometimes repair operations are aborted by the host due to errors returned by algorithms for performing DDR5 hPPRs.

The present inventors have recognized that a solution to these and other problems can include providing a repair flag token counter for use in CXL memory systems. The repair flag token counter tracks DRAM media repair element availability. The host and/or the CMM device can use the repair flag token counter to predict, perform or schedule a maintenance operation. Token counter values can be stored in non-volatile memory. Token counter values can vary by DRAM die or bank, as described herein. Embodiments discussed herein provide systems and methods to use the repair token counter to predict when maintenance operations should be performed. This allows users to plan downtime and increases RAS of memory devices.

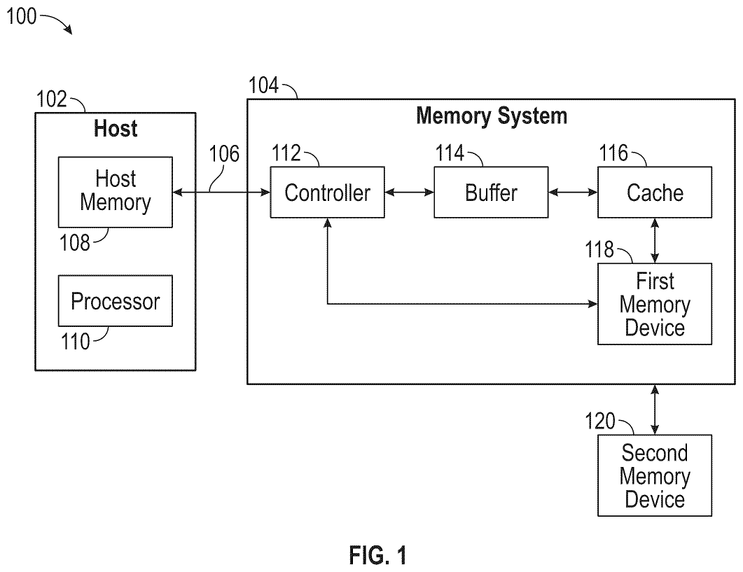

FIG. 1 illustrates generally a block diagram of an example of a computing system 100 including a host device 102 and a memory system 104. The host device 102 includes a central processing unit (CPU) or processor 110 and a host memory 108. In an example, the host device 102 can include a host system such as a personal computer, a desktop computer, a digital camera, a smart phone, a memory card reader, and/or Internet-of-things enabled device, among various other types of hosts, and can include a memory access device, e.g., the processor 110. The processor 110 can include one or more processor cores, a system of parallel processors, or other CPU arrangement.

The memory system 104 includes a controller 112, a buffer 114, a cache 116, and a first memory device 118. The first memory device 118 can include, for example, one or more memory modules (e.g., single in-line memory modules, dual in-line memory modules, etc.). The first memory device 118 can include volatile memory and/or non-volatile memory and can include a multiple-chip device that comprises one or multiple different memory types or modules. In an example, the computing system 100 includes a second memory device 120 that interfaces with the memory system 104 and the host device 102.

The host device 102 can include a system backplane and can include a number of processing resources (e.g., one or more processors, microprocessors, or some other type of controlling circuitry). The computing system 100 can optionally include separate integrated circuits for the host device 102, the memory system 104, the controller 112, the buffer 114, the cache 116, the first memory device 118, the second memory device 120, any one or more of which may comprise respective chiplets that can be connected and used together. In an example, the computing system 100 includes a server system and/or a high-performance computing (HPC) system and/or a portion thereof. Although the example shown in FIG. 1 illustrates a system having a Von Neumann architecture, embodiments of the present disclosure can be implemented in non-Von Neumann architectures, which may not include one or more components (e.g., CPU, ALU, etc.) often associated with a Von Neumann architecture.

In an example, the first memory device 118 can provide a main memory for the computing system 100, or the first memory device 118 can comprise accessory memory or storage for use by the computing system 100. In an example, the first memory device 118 or the second memory device 120 includes one or more arrays of memory cells, e.g., volatile and/or non-volatile memory cells. The arrays can be flash arrays with a NAND architecture, for example. Embodiments are not limited to a particular type of memory device. For instance, the memory devices can include RAM, ROM, DRAM, SDRAM, PCRAM, RRAM, and flash memory, among others.

In embodiments in which the first memory device 118 includes persistent or non-volatile memory, the first memory device 118 can include a flash memory device such as a NAND or NOR flash memory device. The first memory device 118 can include other non-volatile memory devices such as non-volatile random-access memory devices (e.g., NVRAM, RcRAM, FeRAM, MRAM, PCM), memory devices such as a ferroelectric RAM device that includes ferroelectric capacitors that can exhibit hysteresis characteristics, a 3-D Crosspoint (3D XP) memory device, etc., or combinations thereof.

In an example, the controller 112 comprises a media controller such as a non-volatile memory express (NVMe) controller. The controller 112 can be configured to perform operations such as copy, write, read, error correct, etc. for the first memory device 118. In an example, the controller 112 can include purpose-built circuitry and/or instructions to perform various operations. That is, in some embodiments, the controller 112 can include circuitry and/or can be configured to perform instructions to control movement of data and/or addresses associated with data such as among the buffer 114, the cache 116, and/or the first memory device 118 or the second memory device 120.

In an example, at least one of the processor 110 and the controller 112 comprises a command manager (CM) for the memory system 104. The CM can receive, such as from the host device 102, a read command for a particular logic row address in the first memory device 118 or the second memory device 120. In some examples, the CM can determine that the logical row address is associated with a first row based at least in part on a pointer stored in a register of the controller 112. In an example, the CM can receive, from the host device 102, a write command for a logical row address, and the write command can be associated with second data. In some examples, the CM can be configured to issue, to non-volatile memory and between issuing the read command and the write command, an access command associated with the first memory device 118 or the second memory device 120. In some examples, the CM can issue, to the non-volatile memory and between issuing the read command and the write command, an access command associated with the first memory device 118 or the second memory device 120.

In an example, the buffer 114 comprises a data buffer circuit that includes a region of a physical memory used to temporarily store data, for example, while the data is moved from one place to another. The buffer 114 can include a first-in, first-out (FIFO) buffer in which the oldest (e.g., the first-in) data is processed first. In some embodiments, the buffer 114 includes a hardware shift register, a circular buffer, or a list.

In an example, the cache 116 comprises a region of a physical memory used to temporarily store particular data that is likely to be used again. The cache 116 can include a pool of data entries. In some examples, the cache 116 can be configured to operate according to a write-back policy in which data is written to the cache without being concurrently written to the first memory device 118. Accordingly, in some embodiments, data written to the cache 116 may not have a corresponding data entry in the first memory device 118.

In an example, the controller 112 can receive write requests (e.g., from the host device 102) involving the cache 116 and cause data associated with each of the write requests to be written to the cache 116. In some examples, the controller 112 can receive the write requests at a rate of thirty-two (32) gigatransfers (GT) per second, such as according to or using a CXL protocol. The controller 112 can similarly receive read requests and cause data stored in, e.g., the first memory device 118 or the second memory device 120, to be retrieved and written to, for example, the host device 102 via an interface 106.

In an example, the interface 106 can include any type of communication path, bus, or the like that allows information to be transferred between the host device 102 and the memory system 104. Non-limiting examples of interfaces can include a peripheral component interconnect (PCI) interface, a peripheral component interconnect express (PCIe) interface, a serial advanced technology attachment (SATA) interface, and/or a miniature serial advanced technology attachment (mSATA) interface, among others. In an example, the interface 106 includes a PCIe 5.0 interface that is compliant with the compute express link (CXL) protocol standard. Accordingly, in some embodiments, the interface 106 supports transfer speeds of at least 32 GT/s.

As similarly described elsewhere herein, CXL is a high-speed central processing unit (CPU)-to-device or CPU-to-memory interconnect designed to enhance compute performance. CXL technology maintains memory coherency between a CPU memory space (e.g., the host memory 108) and memory on attached devices or accelerators (e.g., the first memory device 118 or the second memory device 120), which allows resource sharing for higher performance, reduced software stack complexity, and lower overall system cost. CXL is designed to be an industry open standard interface for high-speed communications as accelerators are increasingly used to complement CPUs in support of emerging data-rich and compute-intensive applications such as artificial intelligence and machine learning.

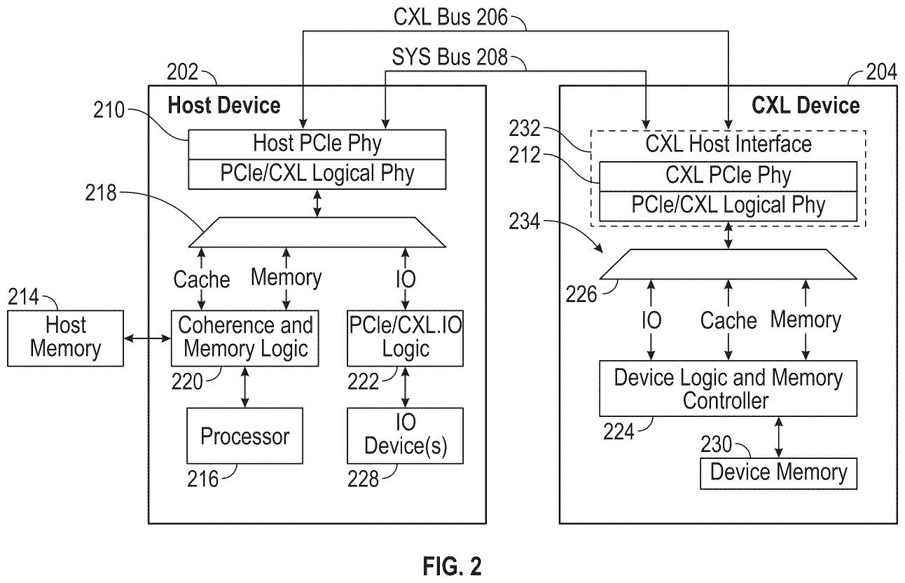

FIG. 2 illustrates generally an example of a CXL system that uses a bus system, including a CXL link bus 206 and a system management bus 208, to connect a host device 202 and a CXL device 204. In an example, the host device 202 comprises or corresponds to the host device 102 and the CXL device 204 comprises or corresponds to the memory system 104 from the example of the computing system 100 in FIG. 1. A memory system command manager (CM) can comprise a portion of the host device 202 or the CXL device 204.

In an example, the system management bus 208 (e.g., corresponding to a portion of the interface 106 from the example of FIG. 1) is configured to support main-band or side-band communications between the host device 202 and the CXL device 204. The system management bus 208 can carry miscellaneous commands or events using PCIe and CXL protocols, such as link speed changes, reset commands issued by the host, and other reliability, availability, and serviceability features.

In an example, the CXL link bus 206 (e.g., corresponding to a portion of the interface 106 from the example of FIG. 1) can support communications using multiplexed protocols for caching (e.g., CXL.cache), memory accesses (e.g., CXL.mem or CXL.memory), and data input/output transactions (e.g., CXL.io). CXL.io can include a protocol based on PCIe that is used for functions such as device discovery, configuration, initialization, I/O virtualization, and direct memory access (DMA) using non-coherent load-store, producer-consumer semantics. CXL.cache can enable a device to cache data from the host memory (e.g., from the host memory 214) using a request and response protocol. CXL.memory can enable the host device 202 to use memory attached to the CXL device 204, for example, in or using a virtualized memory space. The CXL-based memory device can include or use a volatile or non-volatile memory such as it can be characterized by different speeds or latencies. In an example, the CXL-based memory device can include a CXL-based memory controller configured to manage transactions with the volatile or non-volatile memory.

In an example, CXL.memory transactions can be memory load and store operations that run downstream from or outside of the host device 202. CXL memory devices can have different levels of complexity. For example, a simple CXL memory system can include a CXL device that includes, or is coupled to, a single media controller, such as a memory controller (MEMC). A moderate CXL memory system can include a CXL device that includes, or is coupled to, multiple media controllers. A complex CXL memory system can include a CXL device that includes, or is coupled to, a cache controller (and its attendant cache) and to one or more media or memory controllers.

In the example of FIG. 2, the host device 202 includes a host processor 216 (e.g., comprising one or more CPUs or cores) and IO device(s) 228. The host device 202 can comprise, or can be coupled to, host memory 214. The host device 202 can include various circuitry or logic configured to facilitate CXL-based communications and transactions with the CXL device 204. For example, the host device 202 can include coherence and memory logic 220 configured to implement transactions according to CXL.cache and CXL.memory semantics, and the host device 202 can include PCIe logic 222 configured to implement transactions according to CXL.io semantics. In an example, the host device 202 can be configured to manage coherency of data cached at the CXL device 204 using, e.g., its coherence and memory logic 220.

The host device 202 can further include a host multiplexer 218 configured to modulate communications over the CXL link bus 206 (e.g., using the PCIe PHY layer 210). The multiplexing of protocols ensures that latency-sensitive protocols (e.g., CXL.cache and CXL.memory) have the same or similar latency as a native processor-to-processor link. In an example, CXL defines an upper bound on response times for latency-sensitive protocols to help ensure that device performance is not adversely impacted by variation in latency between different devices implementing coherency and memory semantics.

In an example, symmetric cache coherency protocols can be difficult to implement between host processors because different architectures may use different solutions, which in turn can compromise backward compatibility. CXL can address this problem by consolidating the coherency function at the host device 202, such as using the coherence and memory logic 220.

CXL devices can include devices with various architectures and capabilities. For example, a Type 1 CXL device can be a device configured to implement a fully coherent cache without host management. Transaction types used with Type 1 devices can include device-to-host (D2H) coherent transactions and host-to-device (H2D) snoop transactions, among others. A Type 2 CXL device, such as can include or use an attached high-bandwidth memory, can be configured to optionally implement coherent cache and can be host-managed. CXL.cache and CXL.mem transactions are generally supported by Type 2 devices. A Type 3 CXL device, such as a memory expander for the host, can be configured to include or use host-managed memory. A Type 3 device supports CXL.mem transactions.

The CXL device 204 can include various components or logical blocks including a CXL host interface 232 and a device management system 234. In an example, the CXL host interface 232 can be configured to receive and manage various requests and transactions. For example, the CXL host interface 232 can be configured to receive and communicate PCIe resets such as using PERST (PCI Express Reset), Hot Reset, FLR (function level reset), and CXL resets. In an example, the CXL host interface 232 can be configured to receive and communicate DOE Transaction layer packets. In an example, the CXL host interface 232 can be configured to handle side-band requests or other miscellaneous events from PCIe and CXL devices, such as using the CXL link bus 206 or the system management bus 208.

The CXL host interface 232 can include or use multiple CXL interface physical layers 212. The device management system 234 can include, among other things, the device logic and memory controller 224. In an example, the CXL device 204 can comprise a device memory 230 or can be coupled to another memory device. The CXL device 204 can include various circuitry or logic configured to facilitate CXL-based communications and transactions with the host device 202 using the CXL link bus 206. For example, the device logic and memory controller 224 can be configured to implement transactions received using the CXL host interface 232 according to CXL.cache, CXL.memory, and CXL.io semantics. The CXL device 204 can include a CXL device multiplexer 226 configured to control communications over the CXL link bus 206.

In an example, one or more of the coherence and memory logic 220, the device management system 234, and the device logic and memory controller 224 comprises a Unified Assist Engine (UAE) or compute fabric with various functional units such as a command manager (CM), Threading Engine (TE), Streaming Engine (SE), Data Manager or data mover (DM), or other unit. The compute fabric can be reconfigurable and can include separate synchronous and asynchronous flows.

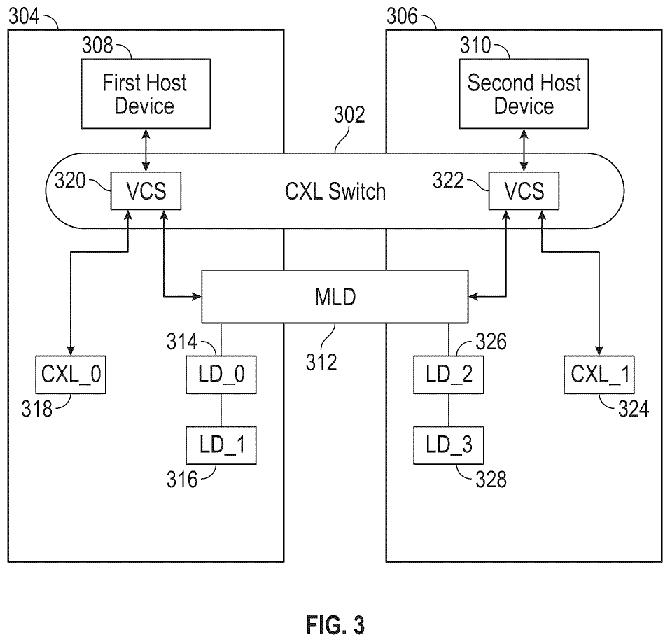

FIG. 3 illustrates generally an example of a portion of a CXL system that can include or use a virtual hierarchy for managing transactions, such as memory transactions with a CXL memory device. The example can include or use real-time telemetry to help facilitate allocation of new or ongoing queues. The example of FIG. 3 includes a first virtual hierarchy 304 and a second virtual hierarchy 306. The first virtual hierarchy 304, the second virtual hierarchy 306, or one or more modules or components thereof can be implemented using the host device 202, the CXL device 204, or multiple instances of the host device 202 or the CXL device 204.

In the example of FIG. 3, the first virtual hierarchy 304 includes a first host device 308 and the second virtual hierarchy 306 includes a second host device 310. A CXL switch 302 can be provided to expose multiple CXL resources to different hosts in the system. In other words, the CXL switch 302 can be configured to couple each of the first host device 308 and the second host device 310 to the same or different resources, such as using respective virtual CXL switches (VCS), such as a first VCS 320 and a second VCS 322, respectively. The CXL switch 302 can be statically configured to couple each host device to respective different resources or the CXL switch 302 can be dynamically configured to the different resources, such as depending on the needs of a particular one of the host devices to execute its respective queues or threads. Accordingly, the CXL switch 302 enables virtual hierarchies and resource sharing among different hosts.

In an example, a fabric manager (FM) can be provided to assign or coordinate connectivity of the CXL switch 302 and can be configured to initiate, dissolve, or reconfigure the virtual hierarchies of the CXL system. The FM can include a baseboard management controller (BMC), an external controller, a centralized controller, or other controller.

In the example of FIG. 3, the CXL switch 302, or the first VCS 320 or the second VCS 322, can coordinate communication between the host devices and various accelerators or other CXL devices. For example, the CXL switch 302 can be coupled to various CXL devices (e.g., a first CXL device 318 or a second CXL device 324), or to various logical devices, such as a single logical device (LD, e.g., a first LD 314, a second LD 316, a third LD 326, or a fourth LD 328) via a multiple logic device (MLD, e.g., an MLD 312). Each CXL device and logical device can represent a respective accelerator or CXL device with its own respective CXL.io configuration space, CXL.mem memory space, and CXL.cache cache space.

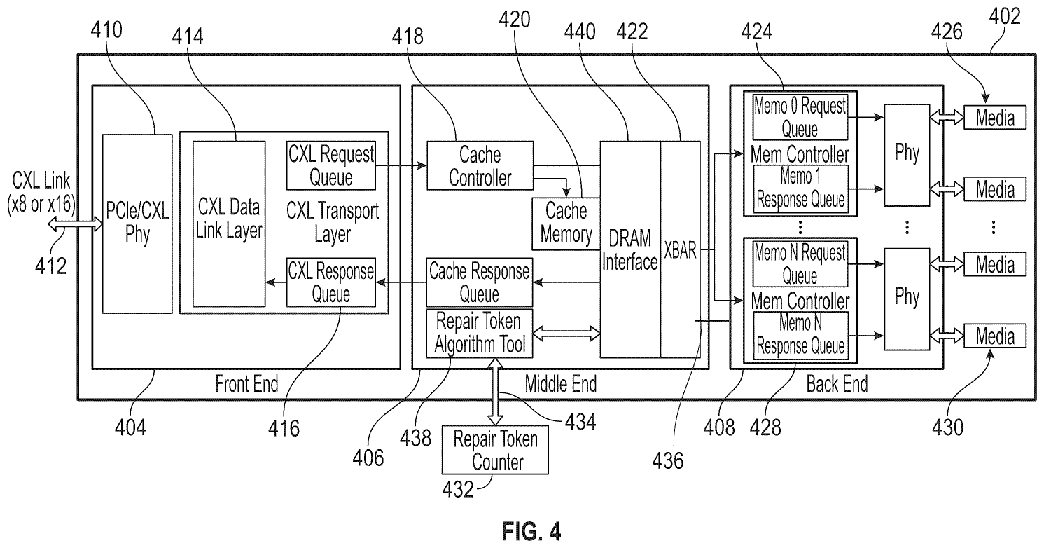

FIG. 4 illustrates generally an example of a CXL device 402 such as a memory device. In an example, the CXL device 402 includes a CXL controller that manages transactions with the host and the CXL device 402 includes a memory controller that manages transactions with a memory. The memory can include or use volatile memory such as DRAM, SDRAM, PCRAM, RRAM, among other kinds of memory. The memory can additionally or alternatively include or use non-volatile memory, such as NAND or NOR flash memory. Although the host and other CXL devices are discussed in various examples herein as a “CXL” host device and a “CXL” accelerator or “CXL” device, other types of hosts and accelerators can similarly be used without including or using CXL protocols.

In an example, the CXL device 402 is a type of accelerator device configured to communicate with one or more hosts via a CXL interface, such as using transactions defined by CXL.io, CXL.mem, and CXL.cache protocols. The CXL device 402 can include a Type 3 CXL device, such as including a memory device with one or multiple memories, such as can include memories of the same type or of different types (e.g., memories exhibiting respective different latency characteristics).

For case of illustration and discussion, the example of the CXL device 402 includes a notional front-end portion 404, a middle-end portion 406, and a back-end portion 408. The portions and components thereof of the CXL device 402 can be differently configured or combined according to different implementations of the CXL device 402.

In the example of FIG. 4, the front-end portion 404 can include a CXL link 412 configured to use a physical layer, CXL PCIe PHY layer 410, to interface with a host device. The front-end portion 404 can further include a CXL data link layer 414 and a CXL transport layer 416 configured to manage transactions between the CXL device 402 and the host. In an example, the CXL transport layer 416 comprises registers and operators configured to manage CXL request queues (e.g., comprising one or more memory transaction requests) and CXL response queues (e.g., comprising one or more memory transaction responses) for the CXL device 402.

In an example, the CXL device 402 can include a memory device that includes a cache (e.g., comprising SRAM) and includes longer-term volatile or non-volatile memory accessible via a memory controller. In the example of FIG. 4, the CXL device 402 includes a cache memory 420 in the middle-end portion 406 of the device. The middle-end portion 406 can include a cache controller 418 configured to monitor requests from the CXL transport layer 416 and identify requests that can be fulfilled using the cache memory 420.

In an example, the cache controller 418 is coupled to a crossbar interface or XBAR interface 422. The XBAR interface 422 can be configured to allow multiple requesters to access multiple memory controllers in parallel, such as including multiple memory controllers in the back-end portion 408 of the CXL device 402. In an example, the XBAR interface 422 provides essentially point-to-point access between the requestor and memory controller and provides generally higher performance than would be available using a conventional bus architecture. The XBAR interface 422 can be configured to receive responses from the back-end portion 408 or receive cache hits from the cache memory 420 and deliver the responses to the front-end portion 404 using a cache response queue.

In the example of FIG. 4, the back-end portion 408 of the CXL device 402 includes multiple memory controllers, including a first memory controller 424 through a Nth memory controller 428. Each of the memory controllers can have or use respective memory request and response queues. Each of the memory controllers can be coupled to respective media or memories, such as can comprise volatile or non-volatile memory. In the illustrated example, the first memory controller 424 is coupled to a first media 426 and the Nth memory controller 428 is coupled to a Nth media 430. In some examples, methods and systems can access data provided by multiple dies (e.g., 18 dies) that are accessed in parallel (e.g., using a 72-bit channel). In an example, each of the multiple dies can include multiple banks (e.g., 16 banks).

Various complexities can arise in CXL systems. For example, repairs may need to be made to the media 426. Repairs should be made in a way to increase RAS of the CXL media 426. As described earlier herein, maintenance operations are supported and defined within CXL specifications. For example, hPPR can be used to repair a bad CXL DRAM media address permanently. DDR4 and DDR5 specifications specify that at least one hPPR row repair address shall be available per bank. However, available DRAM DDR memory systems do not provide a way to count available row repair elements. Providing a way to count available row repair elements can improve predictability of repair and reduce downtime, leading to improved RAS metrics and increased customer satisfaction. The count can be used to identify die or devices for repair ahead of critical failure. Furthermore, as the count is reduced, users can predict the time at which such repair may be needed, which lets users plan for downtime and the possible need of replacement/substitute devices.

For at least these reasons, systems, and methods according to embodiments provide a CXL DRAM Media repair token mechanism to take advantage of DRAM PPR repair address resource availability. Systems and methods according to embodiments use repair token control circuitry 438, provided within the middle-end portion 406, which updates and accesses a repair token counter 432 provided in non-volatile memory over connection 434. A repair flag token of example embodiments can be provided for each bank of the DRAM die. For example, 18*16 tokens, or 288 tokens may be provided in example systems that have 18 dies and 16 banks. However, embodiments are not limited to any particular number of repair flag tokens. Instead, the bank repair token counter 432 is scalable for every DRAM die and for multiple ranks and channels.

The repair flag token can be created during manufacturing of the CXL device 402 or of any portion thereof. In some examples, the repair flag token can be created during CXL device 402 manufacturer or factory testing (e.g., in a final operation or near the end of testing operations).

The repair token control circuitry 438 can manage the repair token counter 432. In examples, this management can include setting, initializing, incrementing, decrementing, or otherwise updating a value stored by the repair token counter 432. In an example, repair tokens, or a value stored by the repair token counter 432, can be based on a count of DRAM repair fuse statuses. The repair token control circuitry 438 can read DRAM repair fuses on each DRAM die by executing a command 436 such as a read request, a Get command or a test mode command. In examples, the command 436 can be provided to a DRAM interface 440. The DRAM interface 440 can include hardware, firmware, or application-specific integrated circuits (ASIC), including bit-bang circuitry, FIFO address circuits, etc. In examples, the command 436 may execute outside the timing of, or without usage/control of the DDR Memory Controller 424 or associated DDR PHY. The DRAM interface 440 can provide the repair token control circuitry 438 access to information regarding availability of the row repair resources.

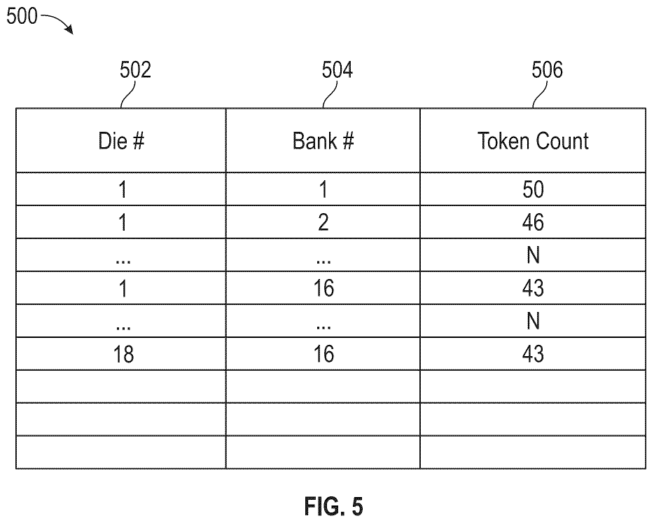

Firmware or other circuitry of the CXL device 402 can generate a repair token counter 432 that associates respective token counts to or with each die in the CXL module (e.g., each die in media 426) or with each bank within each die. FIG. 5 illustrates an example repair token counter data structure 500. As mentioned earlier herein, repair token counter data structure 500 can be stored in persistent (e.g., non-volatile) memory. Counts are stored such that each die 502 and each bank 504 is associated to one token count 506 as shown in FIG. 5. While 18 die are shown in FIG. 5, the media 426 (FIG. 4) can include any number of die, including fewer than 18 die or more than 18 die. Similarly, while 16 banks per die are illustrated in FIG. 5, media 426 (FIG. 4) can include any number of banks per die. Each bank 504 can have different unique counts 506 based on the actual die row repair resource availability.

Referring again to FIG. 4, the repair token control circuitry 438 can track and update the repair token counter 432 each time a host or the CXL device 402 executes a CXL maintenance operation through the repair token control circuitry 438. The repair token control circuitry 438 can ensure integrity of the repair token counter 432 by verifying repair token availability and, by extension, availability of repair resources (e.g., replacement rows for hPPR as described above). Host devices, CPUs, etc. can access the repair token counter using vendor-specific commands or commands specified in CXL specifications (e.g., maintenance operation operational codes or Get/Set operational codes).

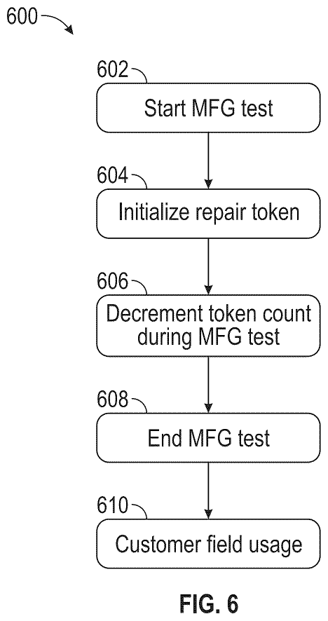

CXL memory devices (e.g., media 426 or other portions of the CXL device 402) may need to be removed from service and sent in for factory repair when a counter reaches a specified threshold number, such as before deterioration of memory device performance becomes noticeable by the end user. Available repair resources can be assessed during manufacturing testing of a CXL memory device as shown in FIG. 6.

FIG. 6 illustrates an example of a method 600 for tracking availability of memory repair resources. The method 600 can be performed by components of FIG. 4, for example the repair token control circuitry 438, repair token counter 432, and DRAM interface 440 or other components of the CXL device 402.

The method 600 can begin at operation 602 with the initiation of a manufacturing test of DRAM memory (e.g., media 426 (FIG. 4)). The manufacturing test can include operations to verify functionality in addition to operations for setting repair token counters according to methods and systems of embodiments.

The method 600 can continue with operation 604 with initialization of one or more repair tokens. The operation 604 can be accomplished by issuing test mode commands to each die of each channel. As a result of operation 604, the repair token control circuitry 438 can obtain the available repair token count of every bank of every die of the media 426 under test. The count can indicate available repair resources for addressable portions of the media 426. The repair token control circuitry 438 can save the repair token count in repair token counter 432 (FIG. 4). In examples, operation 604 can include saving repair token counts in a table or other data structure, such as can be similar to that shown in FIG. 5 and can associate a count with a die and bank. In some examples, token counts may have an initial value that varies based on a type of the respective bank of the plurality of banks. For example, a DRAM Die memory array can have or comprise sixteen banks, each bank having an equal fixed number of repair addresses. During factory testing, a defect is randomly distributed across the array which resulted to non-uniformity of the bank repair addresses usage across all banks resulting the bank repair token to content with different count values when the CXL module is ship to the customer.

The method 600 can continue with operation 606 with decrementing the repair token count during manufacturing test. For example, when a repairable error is detected in a bank during manufacturing test of memory, a repair command can be sent to that bank/to the DRAM. The token count pertaining to that bank can be decremented by the repair token control circuitry 438 and updated in repair token counter 432.

The method 600 can continue with operation 608 by ending the manufacturing test. At operation 608, the memory module (e.g., media 426 or CXL device 402) is shipped or provided to a final customer (e.g., cloud service provider, data center operator, etc.). The shipped device will include the repair token control circuitry 438, repair token counter 432 and DRAM interface 440 so that repair token counts can be accessed by a host system at the final customer.

The method 600 can continue with operation 610 with customer field usage. The repair token control circuitry 438 can report the available repair token count of each bank by accessing the repair token counter 432 periodically, upon host request, etc. During field use, if a repairable error is encountered, the host or customer can request a repair. The repair token control circuitry 438 can update the available repair token in repair token counter 432 upon completion of a repair. When the count reaches a specified threshold count value (for example, when the repair token count has decremented below, e.g., 70% of the token count total, 50% of the total, or other predefined threshold value, for at least one bank, die, or predefined number of banks/dies) then the host or user may take the device out of service. In an example, the device can be physically removed to send in for repairs. By tracking the repair token count, predictions can be made regarding when the device is likely to require service or another repair. A plan can be put in place for replacing the memory temporarily or providing memory backup, thereby avoiding excessive downtime, and extending RAS.

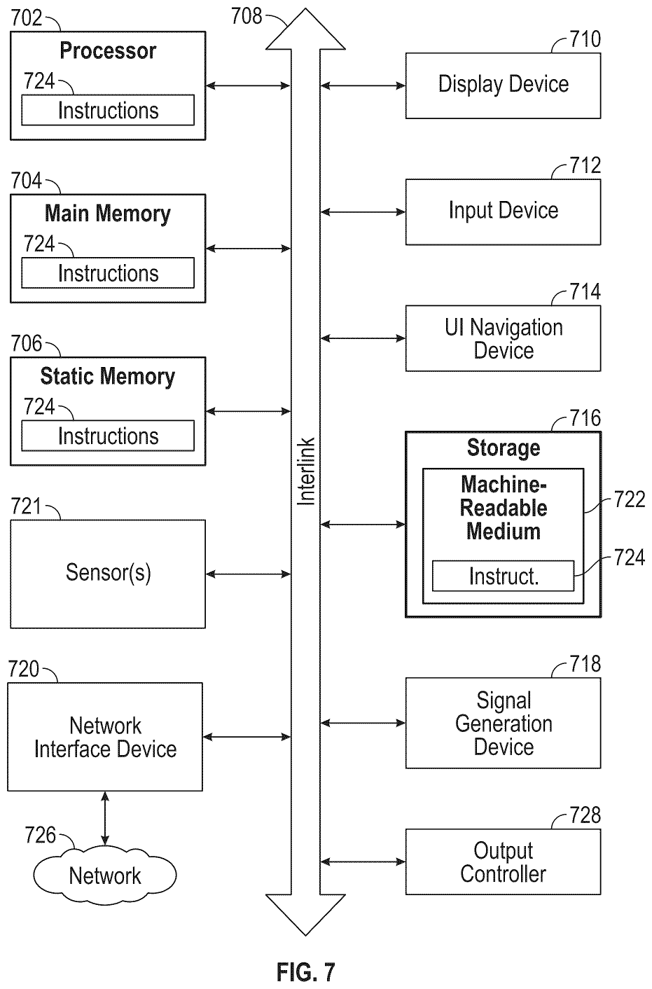

FIG. 7 illustrates a block diagram of an example machine with which, in which, or by which any one or more of the techniques (e.g., methodologies) discussed herein can be implemented. Examples, as described herein, can include, or can operate by, logic or a number of components, or mechanisms in the machine. Circuitry (e.g., processing circuitry) is a collection of circuits implemented in tangible entities of the machine that include hardware (e.g., simple circuits, gates, logic, etc.). Circuitry membership (e.g., as belonging to a host-side device or process, or to an accelerator-side device or process) can be flexible over time. Circuitries include members that can, alone or in combination, perform specified operations when operating. In an example, hardware of the circuitry can be immutably designed to carry out a specific operation (e.g., hardwired) for example using the device logic and memory controller 224, or a host interface circuit, or using a specific command execution unit thereof, such as to track repair resources to predict when a memory device may need to be taken out of service thereby reducing downtime and improving RAS. In an example, the hardware of the circuitry can include variably connected physical components (e.g., command execution units, transistors, simple circuits, etc.) including a machine-readable (e.g., processor-readable) medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time.

In alternative embodiments, the machine can operate as a standalone device or can be connected (e.g., networked) to other machines. In a networked deployment, the machine can operate in the capacity of a server machine, a client machine, or both in server-client network environments. In an example, the machine can act as a peer machine in peer-to-peer (P2P) (or other distributed) network environment. The machine can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Any one or more of the components of the machine can include or use one or more instances of the host device 202 or the CXL device 204 or other component in or appurtenant to the computing system 100. The machine (e.g., computer system) can include a hardware processor 702 (e.g., the host processor 216, the device logic and memory controller 224, a central processing unit (CPU), a graphics processing unit (GPU), a hardware processor core, or any combination thereof), a main memory 704, a static memory 706 (e.g., memory or storage for firmware, microcode, a basic-input-output (BIOS), unified extensible firmware interface (UEFI), etc.), and mass storage device 716 or memory die stack, hard drives, tape drives, flash storage, or other block devices) some or all of which can communicate with each other via an interlink 708 (e.g., bus). The machine can further include a display device 710, an alphanumeric input device 712 (e.g., a keyboard), and a user interface (UI) Navigation device 714 (e.g., a mouse). In an example, the display device 710, the input device 712, and the UI navigation device 714 can be a touch screen display. The machine can additionally include a mass storage device 716 (e.g., a drive unit), a signal generation device 718 (e.g., a speaker), a network interface device 720, and one or more sensor(s) 721, such as a global positioning system (GPS) sensor, compass, accelerometer, or another sensor. The machine can include an output controller 728, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the hardware processor 702, the main memory 704, the static memory 706, or the mass storage device 716 can be, or include, a machine-readable media on which is stored one or more sets of data structures or instructions 724 (e.g., software) embodying or used by any one or more of the techniques or functions described herein. The instructions 724 can also reside, completely or at least partially, within any of registers of the hardware processor 702, the main memory 704, the static memory 706, or the mass storage device 716 during execution thereof by the machine. In an example, one or any combination of the hardware processor 702, the main memory 704, the static memory 706, or the mass storage device 716 can constitute the machine-readable media 722. While the machine-readable media 722 is illustrated as a single medium, the term “machine-readable medium” can include a single medium or multiple media (e.g., a centralized or distributed database, or associated caches and servers) configured to store the one or more instructions 724.

The term “machine-readable medium” (or, equivalently, “processor-readable medium”) can include any medium that is capable of storing, encoding, or carrying instructions for execution by the machine and that cause the machine to perform any one or more of the techniques of the present disclosure, or that is capable of storing, encoding or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks.

In an example, information stored or otherwise provided on the machine-readable media 722 can be representative of the instructions 724, such as instructions 724 themselves or a format from which the instructions 724 can be derived. This format from which the instructions 724 can be derived can include source code, encoded instructions (e.g., in compressed or encrypted form), packaged instructions (e.g., split into multiple packages), or the like. The information representative of the instructions 724 in the machine-readable media 722 can be processed by processing circuitry into the instructions to implement any of the operations discussed herein. For example, deriving the instructions 724 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 724.

In an example, the derivation of the instructions 724 can include assembly, compilation, or interpretation of the information (e.g., by the processing circuitry) to create the instructions 724 from some intermediate or preprocessed format provided by the machine-readable media 722. The information, when provided in multiple parts, can be combined, unpacked, and modified to create the instructions 724. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 724 can be further transmitted or received over a communications network 726 using a transmission medium via the network interface device 720 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 720 can include one or more physical jacks (e.g., Ethernet, coaxial, or phone jacks) or one or more antennas to connect to the network 726. In an example, the network interface device 720 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that can store, encoding or carrying instructions for execution by the machine, and includes digital or analog communications signals or other intangible medium to facilitate communication of such software. A transmission medium is a machine-readable medium.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skills in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A method comprising:
receiving counter values indicating a count of available repair resources for addressable portions of a memory device array;
storing the counter values as repair flag tokens associated with corresponding portions of the addressable portions of the memory device array; and
responsive to detecting an error in a first addressable portion of the addressable portions of the memory device array, changing the repair flag token associated with the first addressable portion where the error was detected.

2. The method of claim 1, wherein the memory device array comprises a plurality of dies and wherein each of the plurality of dies comprises a plurality of banks, and wherein repair flag tokens are associated with each of the plurality of banks.

3. The method of claim 2, wherein the count of available repair resources depends on a type of the respective bank of the plurality of banks.

4. The method of claim 1, wherein receiving the counter values includes in response to a test mode command initializing a manufacturing test of the memory device array.

5. The method of claim 4, wherein the counter values indicate fuse status information associated with repair of a portion of the memory device array.

6. The method of claim 1, further comprising storing the counter values in non-volatile memory.

7. The method of claim 1, further comprising:
receiving a first request for information regarding one or more repair flag token counts subsequent to exiting a manufacturing test; and
initiating a second request to decouple the memory device array responsive to a determination that at least one repair flag token count reached a specified threshold value.

8. The method of claim 7, further comprising predicting a maintenance event, subsequent to exiting the manufacturing test, based on the repair flag token counts.

9. The method of claim 7, further comprising setting the threshold value based on a request from a host device.

10. A system comprising:
a host device; and
a memory device coupled to the host device, wherein the memory device includes a memory device array and control circuitry, the control circuitry configured to:
receive counter values indicating a count of available repair resources for addressable portions of a memory device array;
store the counter values as repair flag tokens associated with respective corresponding portions of the addressable portions of the memory device array; and
responsive to detecting an error in a first addressable portion of the addressable portions of the memory device array, change the repair flag token associated with the first addressable portion where the error was detected.

11. The system of claim 10, wherein the memory device array comprises a plurality of dies and wherein each of the plurality of dies comprises a plurality of banks, and wherein repair flag tokens are associated with each of the plurality of banks.

12. The system of claim 10, wherein the counter values are received in response to a test mode command initializing a manufacturing test.

13. The system of claim 12, wherein the counter values indicate fuse status information associated with repair of a portion of the memory device array.

14. The system of claim 10, further comprising non-volatile memory, and wherein the control circuitry is configured to store the counter values in non-volatile memory.

15. The system of claim 10, wherein the control circuitry is further configured to:
receive a first request for information regarding one or more repair flag token counts subsequent to exiting a manufacturing test; and
initiate a second request to decouple the memory device array responsive to a determination that at least one repair flag token count has decremented below a threshold value.

16. The system of claim 15, wherein the controller is further configured to:
predict a maintenance schedule, subsequent to exiting the manufacturing test, based on the repair flag token counts.

17. The system of claim 10, wherein the controller is further configured to:
receive a request from a host device to repair an error in a portion of the memory device; and
decrement a repair flag token associated with the portion subsequent to performing the repair.

18. The system of claim 10, wherein the memory device is coupled to the host device using a compute express link (CXL) interconnect.

19. A non-transitory processor-readable storage medium, the processor-readable storage medium including instructions that, when executed by a processor circuit, cause the processor circuit to:
receive counter values indicating a count of available repair resources for addressable portions of a memory device array;
store the counter values as repair flag tokens associated with respective corresponding portions of the addressable portions of the memory device array; and
responsive to detecting an error in a first addressable portion of the addressable portions of the memory device array, change the repair flag token associated with the first addressable portion where the error was detected.

20. The non-transitory processor-readable storage medium of claim 19, wherein the instructions further cause the processor circuit to:
receive a first request for information regarding one or more repair flag token counts subsequent to exiting a manufacturing test; and
initiate a second request to decouple the memory device array responsive to a determination that at least one repair flag token count reached a specified threshold value.
